(19) United States
(12) Patent Application Publication
(10) Pub. No.: US 2023/0025921 A1
(43) Pub. Date: Jan. 26, 2023

(54) COLD PLATES AND LIQUID COOLING SYSTEMS FOR ELECTRONIC DEVICES

(71) Applicant: Intel Corporation, Santa Clara, CA (US)

(72) Inventors: Devdatta Kulkarni, Portland, OR (US); Alexey Chinkov, Haifa (IL); Brian Jarrett, Hillsboro, OR (US); Jeff King, Portland, OR (US); John Gulick, Portland, OR (US)

(21) Appl. No.: 17/957,175

(22) Filed: Sep. 30, 2022

(51) Int. Cl. H05K 7/20

(52) U.S. Cl. CPC H05K 7/20254

(57) ABSTRACT

Cold plates and liquid cooling systems for electronic devices are disclosed herein. An example cold plate includes a body defining a cavity. The body has an inlet opening and an outlet opening fluidically coupled to the cavity such that a fluid passageway is defined between the inlet opening and the outlet opening. The cold plate also includes metal foam in the cavity.

### FIELD OF THE DISCLOSURE

This disclosure relates generally to heat management for electronic devices and, more particularly, to cold plates and liquid cooling systems for electronic devices.

### BACKGROUND

Liquid cooling systems are commonly used in computing devices to manage heat generated by the electronic components. For instance, computers often include cooling liquid systems to manage the heat generated by the central processing unit (CPU).

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes composed of disaggregated resources.

FIG. 17 is a schematic diagram of an example liquid cooling system including an example cold plate that can be used in connection with any of the example electronic devices of FIGS. 1-16.

FIG. 18 is an exploded view of an example cold plate including an example fin bank that can be implemented as the example cold plate in FIG. 17.

FIG. 19 is an enlarged view of example metal foam material that can be implemented as the example fin bank of FIG. 18.

FIGS. 20A-20E show an example sequence of operations used to form the example fin bank and assemble the example cold plate of FIG. 18.

FIG. 21 is an exploded view of an example cold plate including metal foam that can be implemented as the example cold plate in FIG. 17.

FIG. 22 is an assembled cross-sectional view of the example cold plate of FIG. 21.

FIGS. 23A-23E show an example sequence of operations used to form the example metal foam and assemble the example cold plate of FIG. 21.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Electronic devices, such as computers, laptops, servers, etc. often include electrical components that generate heat. For example, processor circuitry, hard drives, batteries, and/or other electrical components typically generate heat during operation. The amount of heat generated is often greater in high-power computing areas, such as with artificial intelligence, machine learning, high-speed graphical processing units (GPUs), and accelerators. Heat can negatively affect the performance of an electrical component as well as other nearby components and, thus, negatively impact the performance of the electronic device and/or systems including the device. Therefore, it is important to cool the electronic device and/or its components to reduce (e.g., prevent or limit) negative effects of heat on the performance of the electronic device and/or surrounding components.

Some electronic devices utilize a liquid cooling system. A liquid cooling system includes a cold plate (which may also be referred to as a cooler, cooling device, cooling element, cooling appliance, or cooling block) that is disposed (e.g., located, positioned) on or near the electronic device and/or otherwise in thermal contact with the electronic device. The liquid cooling system includes a pump that pumps cooling liquid, such as a dielectric fluid, through the cold plate. The cooling liquid absorbs heat from the cold plate and thus the electronic device, thereby allowing the temperature of the electronic device to be controlled either at a set temperature or within a range of safe temperatures over which the device can operate properly. The liquid cooling system pumps the heated cooling liquid through a radiator or condenser. In some examples, one or more fans are mounted near the radiator or condenser that force air across the radiator or condenser to reduce the temperature of the cooling liquid. The cooling liquid is then pumped back to the cooler and the cycle is repeated. The amount of heat that can be removed from the electronic device is at least partially dependent on the cooling capability of the cold plate.

Some known cold plates include a set of fins located in a cavity in the cold plate. The fins effectively increase the surface area of the cold plate and help to transfer heat from the electronic device to the cooling liquid. Some cooling systems utilize a two-phase cooling liquid. In particular, as the cooling liquid is heated in the cold plate, the cooling liquid vaporizes into a gaseous form. This transformation from liquid to vapor bubbles increases the heat absorption and improves the cooling capability of the cold plate. Superior performance of two-phase liquid cooling is seen when vapor bubbles start quickly generating and detaching from the surface at a higher frequency with reduced (e.g., minimal) wall superheat. Wall superheat refers to the difference between the wall temperature and the cooling liquid temperature. However, with higher heat loads, the wall superheat tends to increase in known cold plates. For instance, in some known cold plates, the temperature difference between wall temperature and cooling liquid temperature is almost 55° C. The maximum reliability temperature of silicon is around 100 to 110° C. Therefore, these known cold plates have difficulty effectively handling higher total heat loads and higher heat fluxes (e.g., heat flow intensity or density) generated by high-powered electronic devices.

Disclosed herein are example cold plates with improved cooling capabilities and that can handle higher heat loads and/or higher heat fluxes from high performance electronic devices. An example cold plate disclosed herein includes a plurality of fins, referred to as a fin bank, constructed of metal foam. The metal foam may be, for example, copper foam or aluminum foam. The metal foam has an open-cell foam structure, which has a network of voids or cells that are interconnected. Therefore, the surface of the fins has small voids or cells. This surface structure promotes (e.g., increases) bubble formation that results in smaller bubbles and quicker detachment of the bubbles from the surface. In other words, these small voids or cells form nucleation sites for bubble formation and detachment. As such, this surface structure enables the cooling liquid to vaporize more quickly. Therefore, the metal foam acts as a boiling enhancement coating to increase liquid-to-vapor transformation. This boiling enhancement reduces the wall superheat and thereby increases the cooling capability of the cold plate. Increasing the cooling capacity in this manner enables the liquid cooling system to more efficiently absorb heat from the electronic device, thereby reducing the temperature of the electronic device and/or its components and enabling the electronic device to operate more efficiently.

As noted above, the use of liquids to cool electronic components is being explored for its benefits over more traditional air cooling systems, as there are increasing needs to address thermal management risks resulting from increased thermal design power in high performance systems (e.g., CPU and/or GPU servers in data centers, accelerators, artificial intelligence computing, machine learning computing, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic component(s). An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

A liquid cooling system can involve at least one of single-phase cooling or two-phase cooling. As used herein, single-phase cooling means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase cooling means the cooling fluid (in this case, a cooling liquid) vaporizes or boils from the heat generated by the electronic components to be cooled, thereby changing from the liquid phase to the vapor phase. The gaseous vapor may subsequently be condensed back into a liquid (e.g., via a condenser) to again be used in the cooling process. Such cooling fluids are referred to herein as two-phase cooling fluids, liquids, or coolants. Notably, gases (e.g., air) can also be used to cool components and, therefore, may also be referred to as a cooling fluid and/or a coolant. However, indirect cooling and immersion cooling typically involve at least one cooling liquid (which may or may not change to the vapor phase when in use). Example systems, apparatus, and associated methods to improve cooling systems and/or associated cooling processes are disclosed herein.

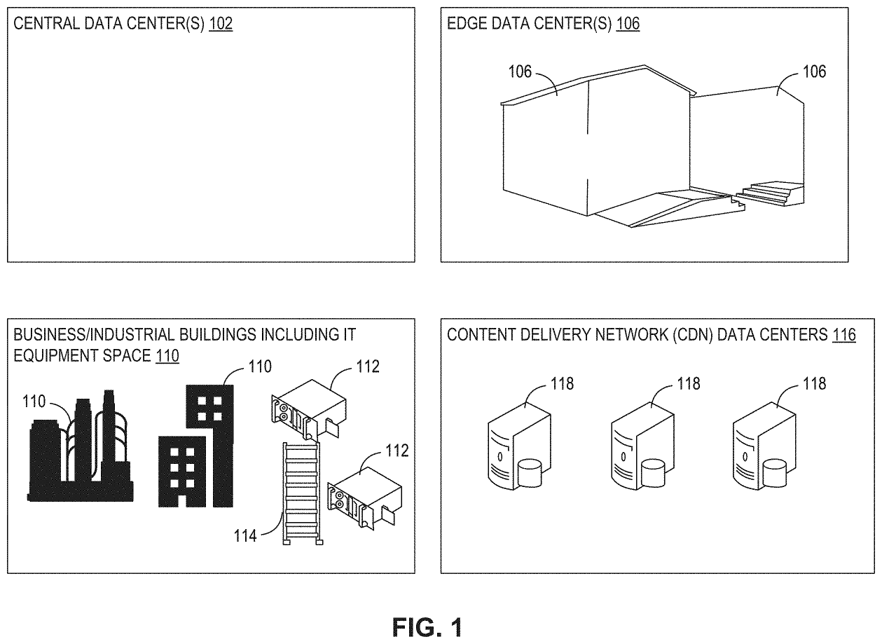

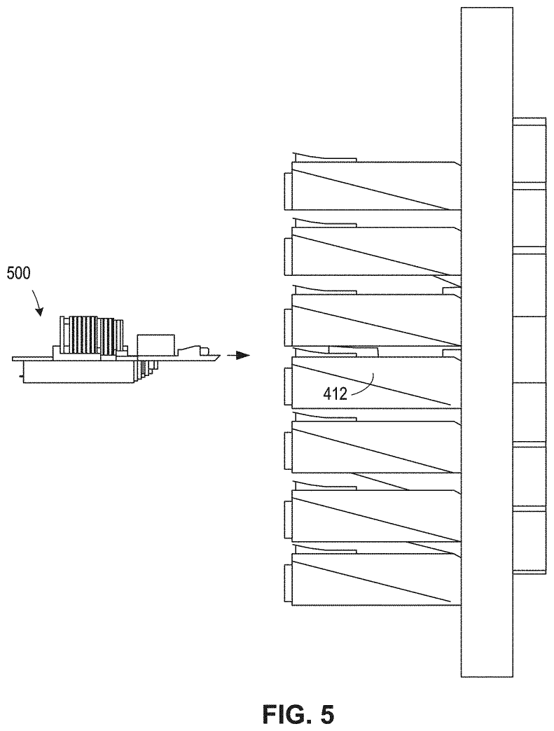

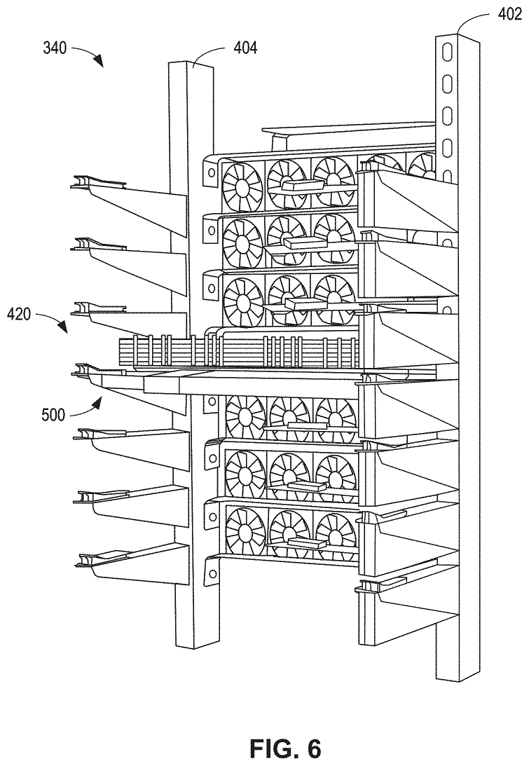

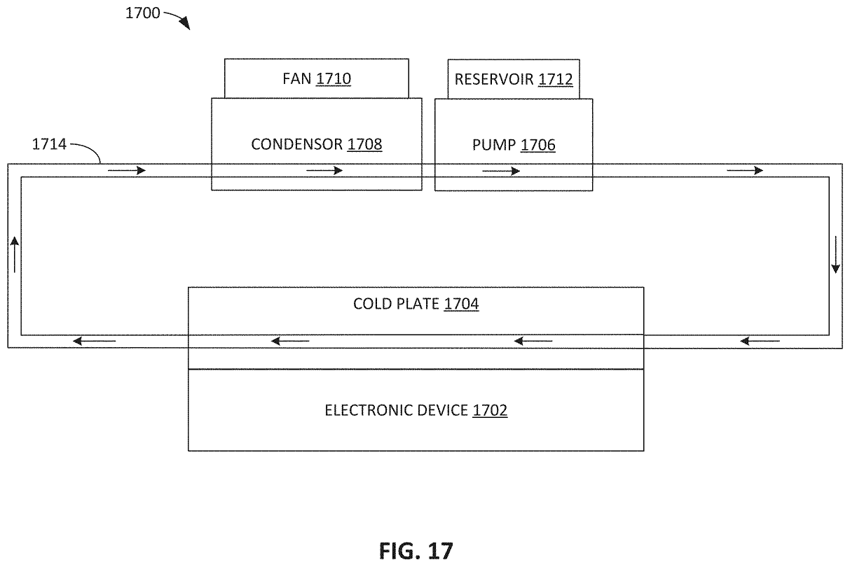

FIGS. 1-16 illustrate example environments and example electronic components with which example cold plates and example cooling systems disclosed herein can be implemented. However, the example liquid cooling systems and example cold plates disclosed herein can also be used in connection with any type of system or device where it is desirable to provide cooling, such as in a vehicle. Example liquid cooling systems and example cold plates are disclosed in further detail in connection with FIGS. 17, 18, 19, 20A-20E, 21, 22, and 23A-23E.

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. The example environments of FIG. 1 can be part of an edge computing system. For instance, the example environments of FIG. 1 can include edge data centers or micro-data centers 106. The edge data center(s) 106 can include, for example, data centers located at a base of a cell tower. The edge data center(s) 106 include respective housings that store server(s), where the server(s) can be in communication with, for instance, the server(s) stored at the central data center(s) 102, client devices, and/or other computing devices in the edge network.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network. The example environment(s) of FIG. 1 include content delivery network (CDN) data center(s) 116. The CDN data center(s) 116 of this example include server(s) 118 that cache content such as images, webpages, videos, etc. accessed via user devices.

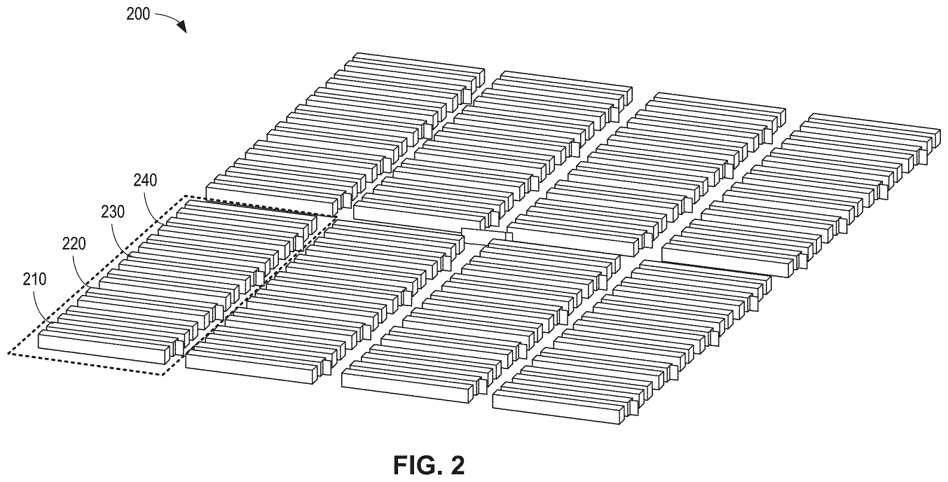

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks.

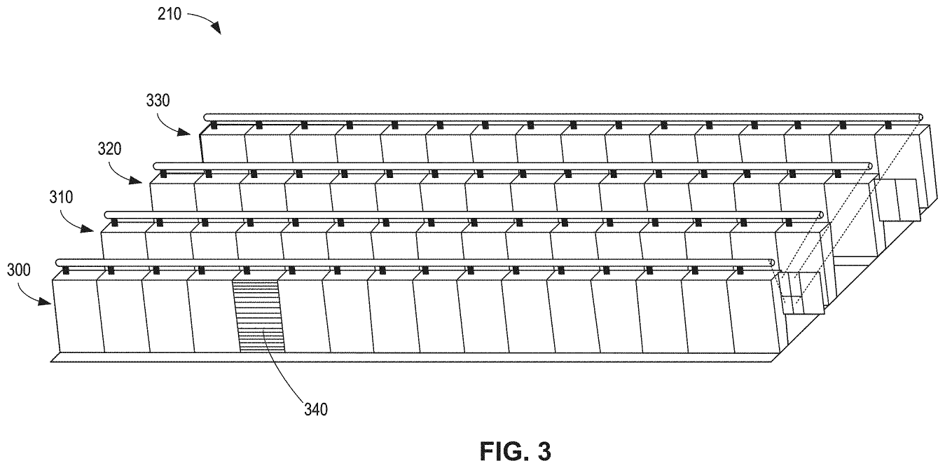

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds.

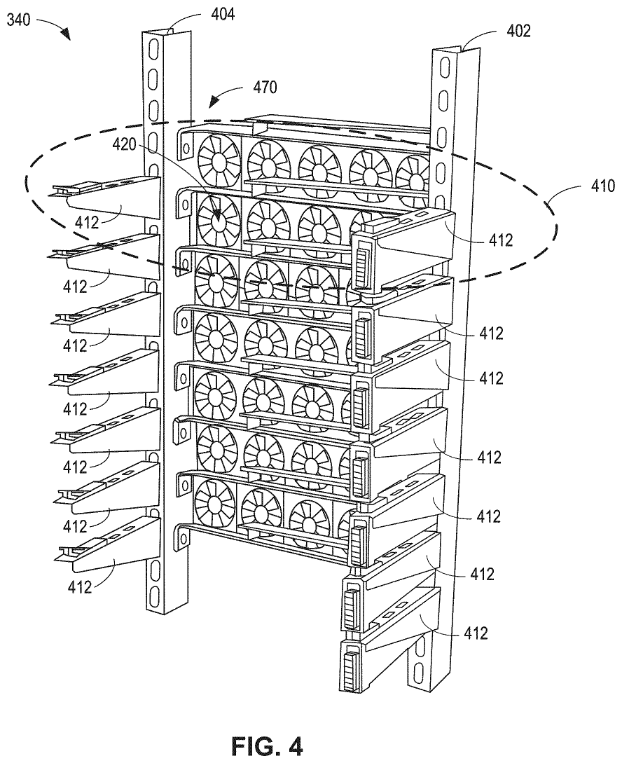

FIGS. 4-6 illustrate an example rack 340 of the data center 200. As shown in the illustrated example, the rack 340 includes two elongated support posts 402, 404, which are arranged vertically, and one or more horizontal pairs 410 of elongated support arms 412 (identified in FIG. 4 via a dashed ellipse) configured to support a sled of the data center 200. A given pair 410 of the elongated support arms 412 defines a sled slot 420 of the rack 340. The illustrative rack 340 also includes a fan array 470 coupled to the cross-support arms of the rack 340. In other examples, some or all of the sleds 500 can include on-board cooling systems. Further, in some examples, the sleds 500 and/or the racks 340 may include and/or incorporate a liquid cooling system to facilitate cooling of electronic component(s) on the sleds 500.

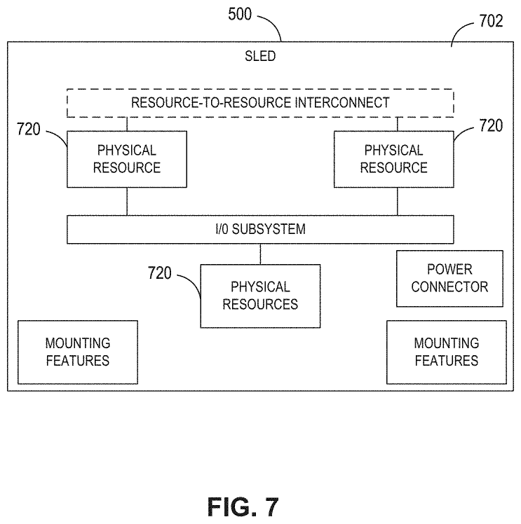

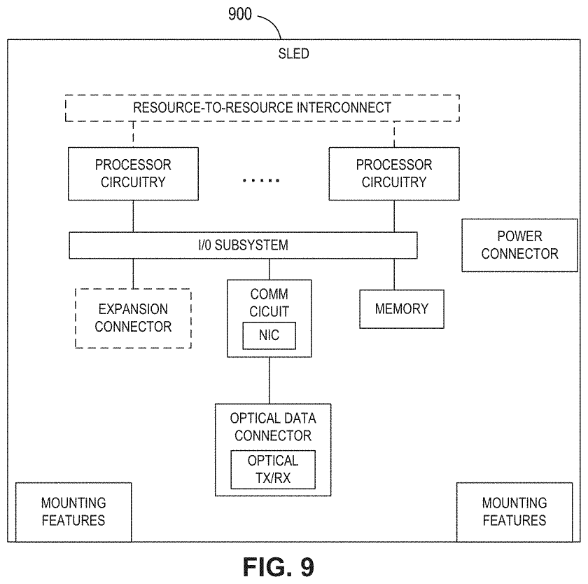

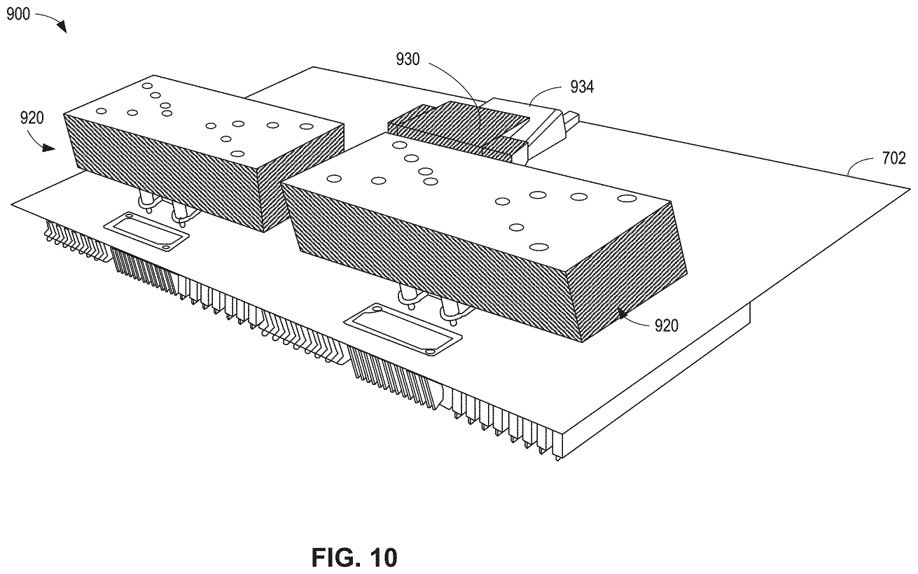

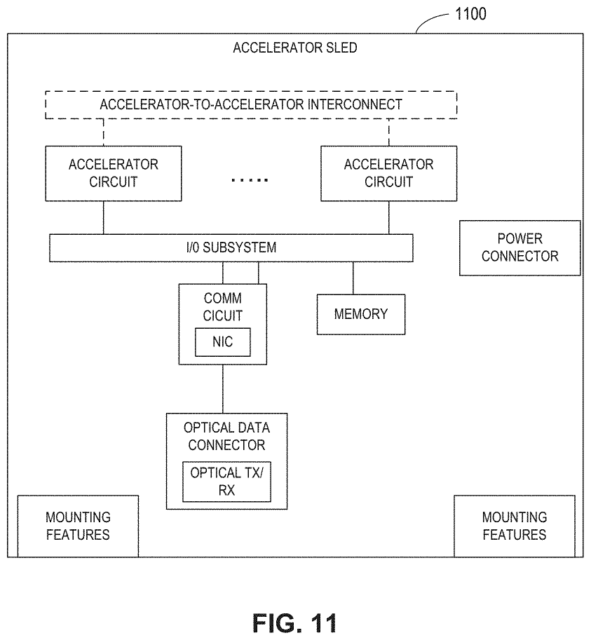

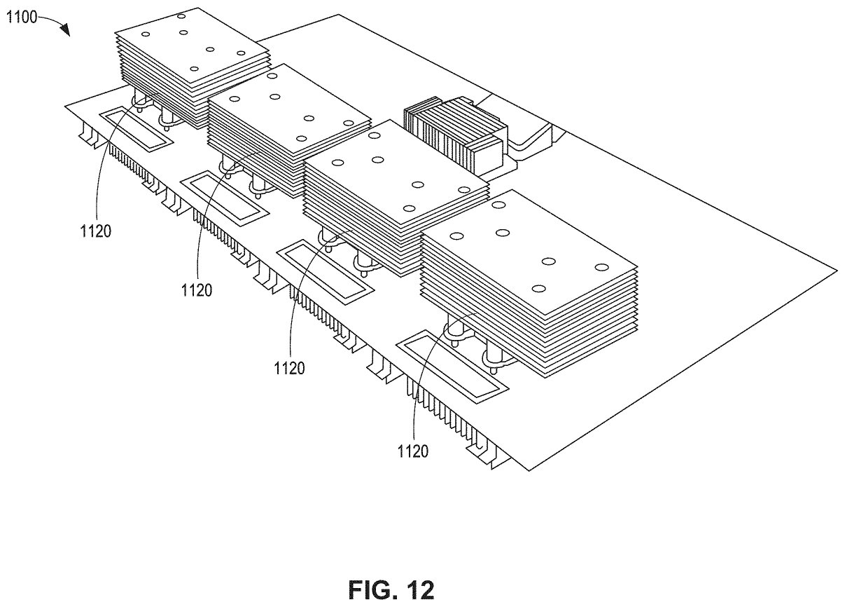

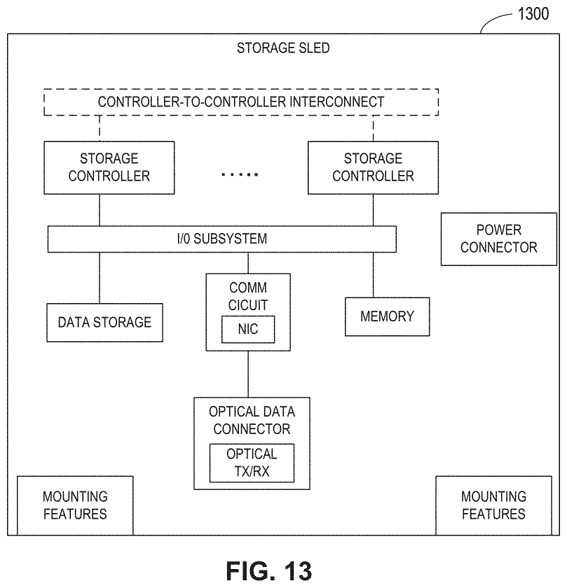

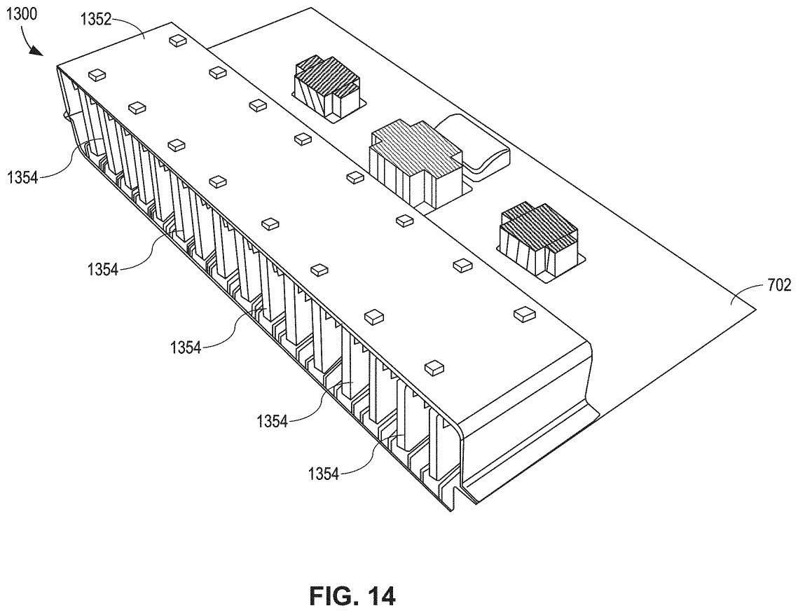

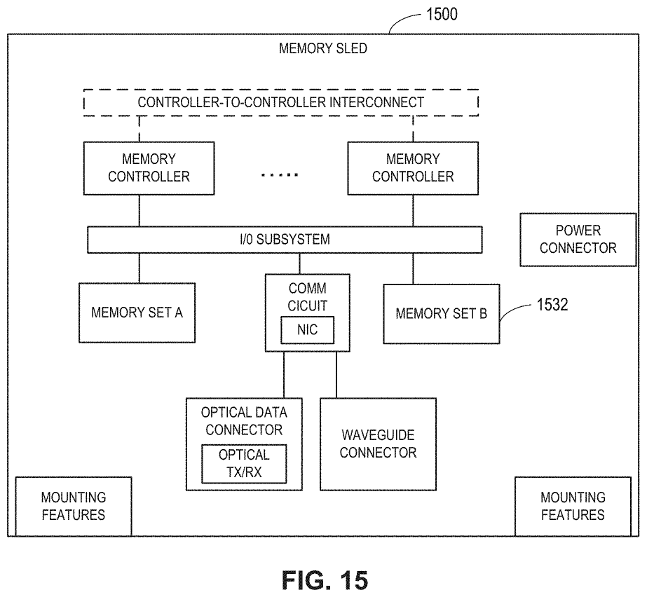

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15. The sled 500 can include one or more physical resources 720 mounted to a substrate 702.

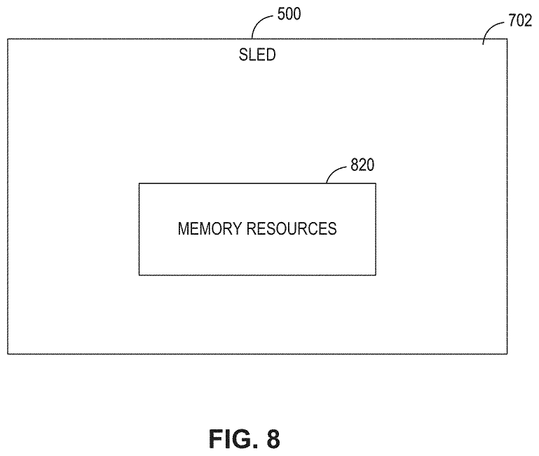

Referring now to FIG. 8, in addition to the physical resources 720 mounted on the substrate 702, the sled 500 also includes one or more memory devices 820 mounted to the substrate 702. Referring now to FIG. 9, in some examples, the sled 500 may be implemented as a compute sled 900. The compute sled 900 is optimized, or otherwise configured, to perform compute tasks. Referring now to FIG. 10, an illustrative example of the compute sled 900 is shown. As shown, processor circuitry 920, communication circuit 930, and optical data connector 934 are mounted to the substrate 702.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. As shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

Referring now to FIG. 13, in some examples, the sled 500 may be implemented as a storage sled 1300. The storage sled 1300 is configured, to store data in a data storage 1350 local to the storage sled 1300. Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354.

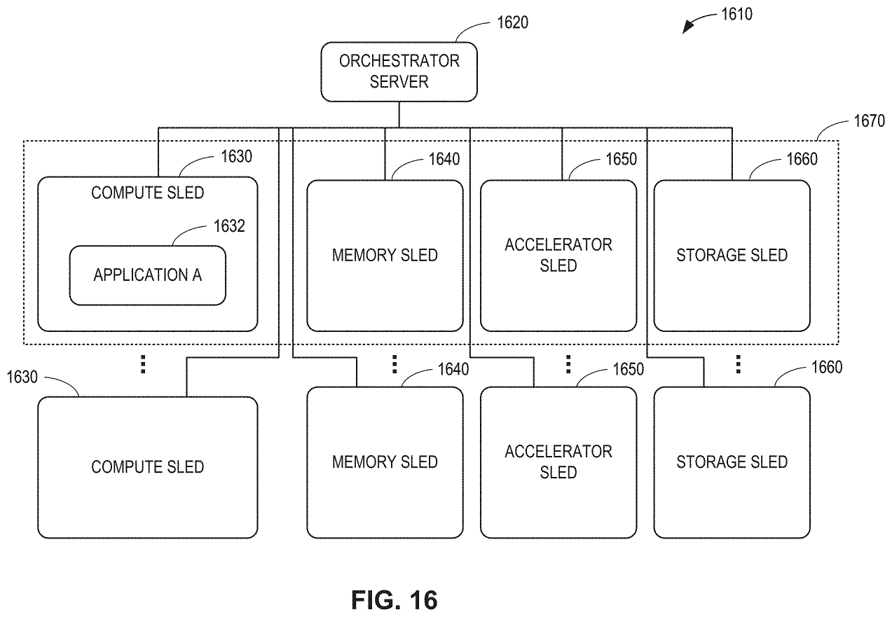

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory local to the memory sled 1300. Referring now to FIG. 16, a system 1610 for executing one or more workloads (e.g., applications) may be implemented in accordance with the data center 200. In the illustrative example, the system 1610 includes an orchestrator server 1620, which may be implemented as a managed node including a compute device that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container).

FIG. 17 is a schematic illustration of an example liquid cooling system 1700 constructed in accordance with teachings of this disclosure. The example liquid cooling system 1700 can be used to transport and/or reduce heat generated by one or more heat generating devices, such an example electronic device 1702. The example electronic device 1702 can be any electronic device that generates heat when operating, such as any of the example electronic devices/components disclosed in connection with FIGS. 1-17 (e.g., a CPU, an XPU, a GPU, an accelerator, etc.). Heat tends to degrade the efficiency of computing circuitry. In particular, heat can lower the electrical resistance of objects, therefore increasing the current in those objects. The example liquid cooling system 1700 can be used to remove heat from the heat generating components to thereby reduce the temperature and improve performance of the electronic device 1702.

In the illustrated example, the example liquid cooling system 1700 includes an example cold plate 1704, an example pump 1706, an example condenser 1708, an example fan 1710, and an example reservoir 1712. The example cold plate 1704 may also be referred to as a cooler or cooling block. The example liquid cooling system 1700 also includes a fluid circuit 1714 that fluidically couples the cold plate 1704, the pump 1706, and the condenser 1708. The condenser 1708 may be referred to as a heat exchanger. The fluid circuit 1714 can include any type and/or number of fluid lines (e.g., hoses, tubes), fluid channels, connectors, valves, and/or a system of the foregoing that fluidically couples two or more of the components. The fluid circuit 1714 has cooling liquid, such as liquid dielectric (e.g., mineral oil, silicon oil, etc.). In other examples, the cooling liquid can be another type of liquid, such as water, deionized water, refrigerant, and/or a glycol/water solution.

In some examples, the cold plate 1704 is coupled directly or indirectly (e.g., via one or more layers) to the electronic device 1702. For example, the cold plate 1704 can be coupled to the electronic device 1702 via one or more threaded fasteners (e.g., bolts, screws, etc.), welding, soldering, adhesives, etc. In the illustrated example, the cold plate 1704 is on (e.g., disposed on) the electronic device 1702. In some examples, the cold plate 1704 is in direct contact with the electronic device 1702. For example, the cold plate 1704 can be in direct contact with a top surface of a casing or integrated heat spreader of the electronic device 1702. In other examples, one or more intermediary components or layers are disposed between the cold plate 1704 and the electronic device 1702. In other examples, the cold plate 1704 is disposed close to, but spaced apart from, the electronic device 1702. The cold plate 1704 can be constructed of any thermally conductive material, such as a metal. In some examples, the cold plate 1704 is at least partially constructed of copper. In other examples, the cold plate 1704 can be constructed of other materials, such as aluminum, brass, steel, etc.

During operation, the pump 1706 pumps the cooling liquid through the fluid circuit 1714. The cooling liquid flows through one or more fluid passageways in the cold plate 1704. The cold plate 1704 absorbs heat from the electronic device 1702, which is transferred to the cooling liquid passing through the cold plate 1704, thereby reducing the temperature of the electronic device 1702. In some examples, the cooling liquid transforms from a liquid phase into a gaseous or vapor phase in the cold plate 1704. The cooling liquid/vapor is then transferred via the fluid circuit 1714 to the condenser 1708. The condenser 1708 dissipates the heat to the surrounding ambient air and the vapor condenses back into liquid form. In some examples, the fan 1710 is activated to direct ambient air across the condenser 1708 to help further reduce the temperature of the cooling liquid. The cooling liquid, after being cooled in the condenser 1708, is pumped back to the cold plate 1704 and the cycle is repeated. The fluid circuit 1714 of this example includes a continuous flow of cooling liquid/vapor. In some examples, the reservoir 1712 contains additional cooling liquid to ensure a sufficient amount of cooling liquid is maintained in the fluid circuit 1714. As such, the cooling liquid flowing through the cold plate 1704 absorbs the heat from the electronic device 1702 to reduce the temperature of the circuitry in the electronic device 1702. This enables for example, processor circuitry and/or other components to operate at higher frequencies to meet higher processing demands. This also enables processor circuitry and/or other components to operate at high powers before hitting a temperature limit in the electronic device 1702.

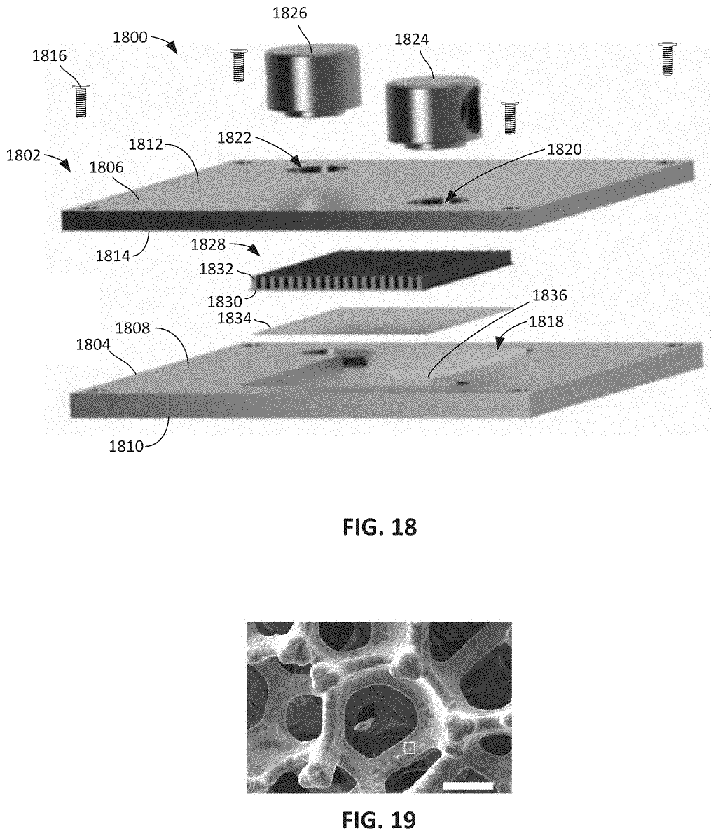

FIG. 18 is an exploded view of an example cold plate 1800 constructed in accordance with teachings of this disclosure. The example cold plate 1800 is an example implementation of the cold plate 1704 in the liquid cooling system 1700 of FIG. 17. In the illustrated example, the cold plate 1800 includes a housing or body 1802. In this example, the body 1802 includes two body components, including a base 1804 and a lid 1806 that is coupled to the base 1804. The base 1804 and the lid 1806 may be constructed of metal, such as copper or aluminum. For example, the base 1804 and the lid 1806 may be blocks of copper or aluminum. The base 1804 has a first side 1808 and a second side 1810 opposite the first side 1808. The lid 1806 has a first side 1812 and a second side 1814 opposite the first side 1812. When the cold plate 1800 is assembled, the lid 1806 is coupled to the first side 1808 of the base 1804. For instance, the second side 1814 of the lid 1806 is in contact with the first side 1808 of the base 1804. In some examples, the base 1804 and the lid 1806 are coupled via one or more threaded fasteners 1816 (one of which is referenced in FIG. 18). In some examples, the threaded fasteners 1816 also couple the cold plate 1800 to the electronic device 1702 (FIG. 17). In other examples, the base 1804 and the lid 1806 are coupled via other chemical and/or mechanical fasteners (e.g., an adhesive, welding, a rivet, etc.).

In the illustrated example, the body 1802 defines a cavity 1818. In this example, the cavity 1818 is formed or defined in the base 1804 (e.g., in the first side 1808 of the base 1804). In some examples, the cavity 1818 is formed via stamping. The body 1802 also has an inlet opening and an outlet opening fluidically coupled to the cavity 1818 such that a fluid passageway is defined between the inlet opening and the outlet opening. For example, in the illustrated example, the lid 1806 has an inlet opening 1820 and an outlet opening 1822, extending between the first and second sides 1812, 1814. When the cold plate 1800 is assembled, the inlet opening 1820 and the outlet opening 1822 are aligned with a portion of the cavity 1818. As such, the inlet opening 1820, the cavity 1818, and the outlet opening 1822 define a fluid flow passageway through the body 1802. When cooling liquid is supplied to the inlet opening 1820, the cooling liquid flows through the inlet opening 1820, through the cavity 1818, and out of the outlet opening 1822. In some examples, the cold plate 1800 includes connectors 1824, 1826 in the inlet and outlet openings 1820, 1822, respectively. The connectors 1824, 1826 are used for connecting a fluid line (e.g., a hose, a tube, a pipe, etc.) of the fluid circuit 1714 (FIG. 17) to the inlet and outlet openings 1820, 1822, respectively. While in this example the cavity 1818 is formed in the base 1804, in other examples, the cavity 1818 can be partially or fully formed in the lid 1806. Further, the inlet and/or outlet openings 1820, 1822 can be formed on other sides or surfaces of the base 1804 and/or the lid 1806 than shown in the above example.

To increase heat absorption while the cooling liquid is flowing through the cavity 1818, the cold plate 1800 can include a plurality of fins. In this example, the cold plate 1800 includes an example fin bank 1828. In the illustrated example, the fin bank 1828 includes a base plate 1830 and a plurality of fins 1832 (one of which is referenced in FIG. 18) extending from the base plate 1830. The fin bank 1828 may include any number of fins 1832. In this example, the fins 1832 are parallel to and spaced apart from each other. In some examples, the fins 1832 are straight. In other examples the fins 1832 can be curved or shaped differently. When the cold plate 1800 is assembled, the fin bank 1828 is disposed in the cavity 1818. During operation, the cooling liquid flows through the cavity 1818 and along the fins 1832 of the fin bank 1828. The fins 1832 of the fin bank 1828 effectively increase the surface area of the cold plate 1800 to achieve greater heat transfer between the cold plate 1800 and the cooling liquid flowing through the cold plate 1800.

In some examples, the fin bank 1828 is coupled to the base 1804 in the cavity 1818. For example, as shown in FIG. 18, the cold plate 1800 includes a piece of braze film 1834. The braze film 1834 is disposed between the base plate 1830 of the fin bank 1828 and a surface 1836 of the base 1804 in the cavity 1818. During assembly/manufacture, the cold plate 1800 is heated in a brazing oven, which melts or softens the braze foil 1834 and thereby joins the fin bank 1828 and the base 1804. In other examples, the fin bank 1828 can be coupled to the base 1804 in other manners, such as soldering, using an adhesive, using fasteners, etc.

In this example, the fin bank 1828 is constructed of metal foam. For example, the fin bank 1828 may be a substantially solid block or piece of metal foam. The shape of the fin bank 1828 can be formed by cutting or stamping a block of metal foam, examples of which are disclosed in further detail herein. In some examples, the fin bank 1828 is constructed of copper foam. In other examples, the fin bank 1828 can be constructed of another type of metal foam material, such as a nickel foam, an aluminum foam, a steel foam, or a combination of metal foams. In some examples, the metal foam has a coating, such as a bronze coating. In other examples, the metal foam is not coated, sintered, or plated. In some examples, the metal foam of the fin bank 1828 is an open-cell-structure foam material. In an open-cell-structure foam material, the cells (sometimes referred to as pores, voids or cavities) in the foam material are interconnected and a form a network of channels. For example, FIG. 19 is an example scanning electron microscope (SEM) image of a metal foam material with an open-cell-structure. The metal foam has cells that are interconnected to form a network of channels. In some examples, the metal foam includes a three-dimensional network of interconnected ligaments (e.g., copper ligaments) that form the open-cell network. In some examples, the metal foam has a relative density of 3-12%. Relative density is the percentage of a given volume occupied by the given material (e.g., metal). In other examples, the metal foam can have a relative density that is higher or lower. In some examples, the metal foam is a compressible metal foam. In some examples, the metal foam can be compressed up to a maximum of 70% relative density. In other examples, the metal foam can be compressed up to another relative density (e.g., 50%). In some examples, the metal foam has a cell size of 0.3-5 millimeters (mm). In other examples, the cell size can be smaller or larger. In some examples, the metal foam has pores per inch (PPI) of 5, 10, 20, or 40, for example. In other examples, the metal foam can have PPI of other amounts (e.g., 50, 60, etc.). This network of channels enables the cooling liquid to flow through the material of the fin bank 1828. Further, depending on the size of the cells, the metal foam material wicks the cooling liquid, thereby helping to move the cooling fluid through the cavity 1818. Thus, the cold plate 1800 include metal foam in the cavity 1818, and, in this example, the metal foam is included in the find bank 1828.

Therefore, because the fin bank 1828 is constructed of a metal foam, the surfaces of the fins 1832 are not smooth. Instead, the surfaces of the fins 1832 have small openings or voids formed by the mesh strands or ligaments of the metal material. These voids on the surface form nucleation sites for bubbles to form and depart from the surface of the fins 1832 and the base plate 1830. Further, the reduced material on the surface results in lower surface tension needed to detach from the surface. This surface structure promotes smaller bubbles that generate and depart at a higher frequency than known fin banks. As such, the cooling liquid can more easily convert from the liquid form to the gaseous or vapor form, which improves the cooling capability of the cold plate 1800. The example cold plate 1800 increases the amount of energy per unit area that can be removed and, thus, can remove more energy for the same area.

While in this example the fin bank 1828 includes the base plate 1830 and the fins 1832, in other examples the fins 1832 may not be connected by a base plate. Instead, individual fins of metal foam material can be separately coupled to the base 1804.

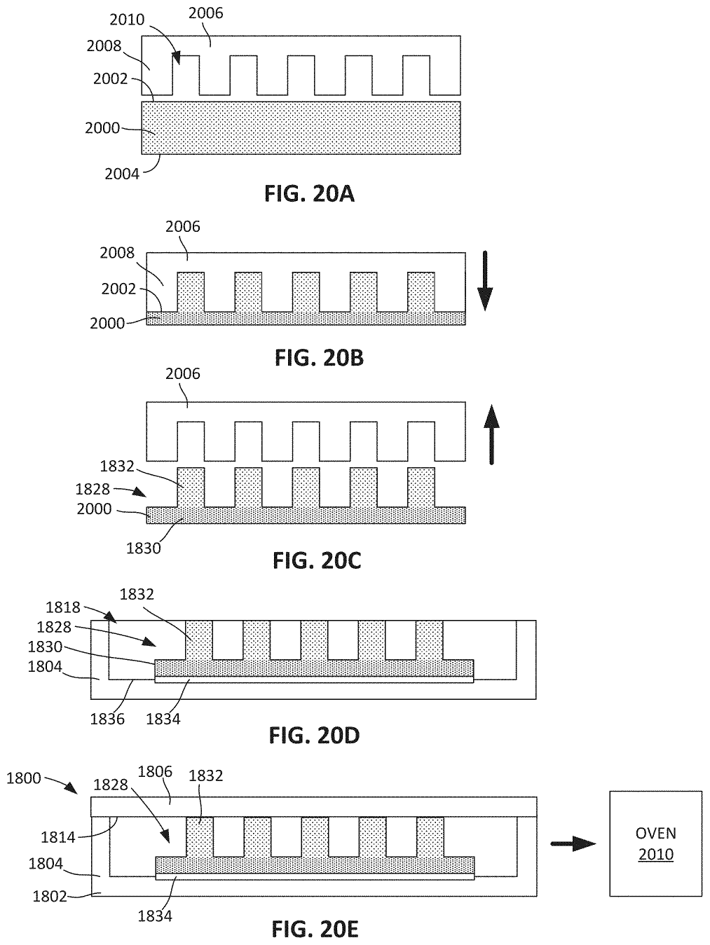

FIGS. 20A-20E show an example sequence of operations to form the example fin bank 1832 and assemble the example cold plate 1800. FIG. 20A shows an example block or piece of metal foam 2000. In some examples, the metal foam 2000 is a rectangular block of metal foam. The metal foam 2000 may be selected to have a desired thickness, porosity, and/or size. The metal foam 2000 may be any type of metal foam, such as copper foam or aluminum foam. The metal foam 2000 has a first side 2002 and a second side 2004 opposite the first side 2002. FIG. 20A also shows an example tool 2006 (e.g., a mold, a compression tool). The tool 2006 may be constructed of high strength material such as stainless steel. As shown in FIG. 20A, the tool 2006 has a plurality of teeth or ridges 2008 (one of which is referenced in FIG. 20A) that form channels 2010 (one of which is referenced in FIG. 20A) between the teeth 2008.

As shown in FIG. 20B, the tool 2006 is pushed into the first side 2002 of the metal foam 2000 to compress, stamp, and/or mold the metal foam 2000 into the fin bank 1828 (FIG. 18). The tool 2006 may be pushed into the metal foam 2000 manually or via an automated machine. The teeth 2008 compress sections of the metal foam 2000, and the sections of the metal foam 2000 between the teeth 2008 form the fins 1832 (FIG. 18) of the fin bank 1828.

In FIG. 20C, the tool 2006 is removed. After the tool 2006 is removed, the metal foam 2000 maintains the shape shown in FIG. 20C, which forms the fin bank 1828. In some examples, the metal foam 2000 may expand slightly after the tool 2006 is removed, but the metal foam 2000 may be over-compressed to compensate for this expansion. In some examples, the metal foam 2000 is heated while being compressed, which helps the metal foam 2000 maintain its shape. As shown, the fin bank 1828 has the base plate 1830 and the fins 1832 (one of which is referenced in FIG. 20C) extending from the plate base 1830. Because the teeth 2008 compress sections of the foam material between the fins 1832, the metal foam in the base plate 1830 has a lower porosity than the metal foam in the fins 1832. In some examples, this lower porosity in the base plate 1830 increases capillary effect, which helps move the cooling liquid through the cavity 1818 (FIG. 18). The metal foam 2000 can be compressed to achieve any desired porosity based on the desired capillary effect and/or critical heat flux. In other examples, instead of stamping or compressing the metal foam 2000 to form the fin bank 1828, the metal foam 2000 can be cut into the shape of the fin bank 1828.

As shown in FIG. 20D, the fin bank 1828 is then disposed in the cavity 1818 of the base 1804. In some examples, the braze film 1834 and/or braze paste is disposed on the surface 1836 of the base 1804, between the base 1804 and the surface 1836. In some examples, such as in high pressure applications, braze film and/or braze paste can be disposed on the tops of the fins 1832 (one of which is referenced in FIG. 20D).

Then, as shown in FIG. 20E, the lid 1806 is coupled (e.g., via the fasteners 1816 (FIG. 18)) to the base 1804. In some examples, when the cold plate 1800 is assembled, the tops of the fins 1832 (one of which is referenced in FIG. 20E) contact or engage the second side 1814 of the lid 1806 (e.g., may be coupled to the lid 1806 via brazing). In other examples, the tops of the fins 1832 may be spaced apart from the second side 1814 of the lid 1806. Then, the cold plate 1800 can be placed in a brazing oven 2010 and heated, which melts or softens the braze film 1834 to couple the fin bank 1828 to the body 1802.

An example method of manufacturing disclosed herein includes compressing a block of metal foam with a tool to form a fin bank. The example method can further include disposing the fin bank in a cavity of a body of a cold plate. For example, as shown in FIGS. 20A-20C, the metal foam 2000 is compressed with the tool 2006 to form the fin bank 1828. Then, as shown in FIG. 20D, the fin bank 1828 is disposed in the cavity 1818 of the cold plate 1800. In some examples, the method includes coupling the fin bank to the body of the cold plate. In some examples, the fin bank is coupled to the body via brazing. Therefore, in some examples, the method may include heating the cold plate in a brazing oven to couple the fin bank to the body. For example, as shown in FIG. 20E, the cold plate 1800 can be heated in the brazing oven 2010 to melt the braze film 1834 and couple the fin bank 1828 to the body 1802. In other examples, the fin bank 1828 can be coupled to the body 1802 in other manners.

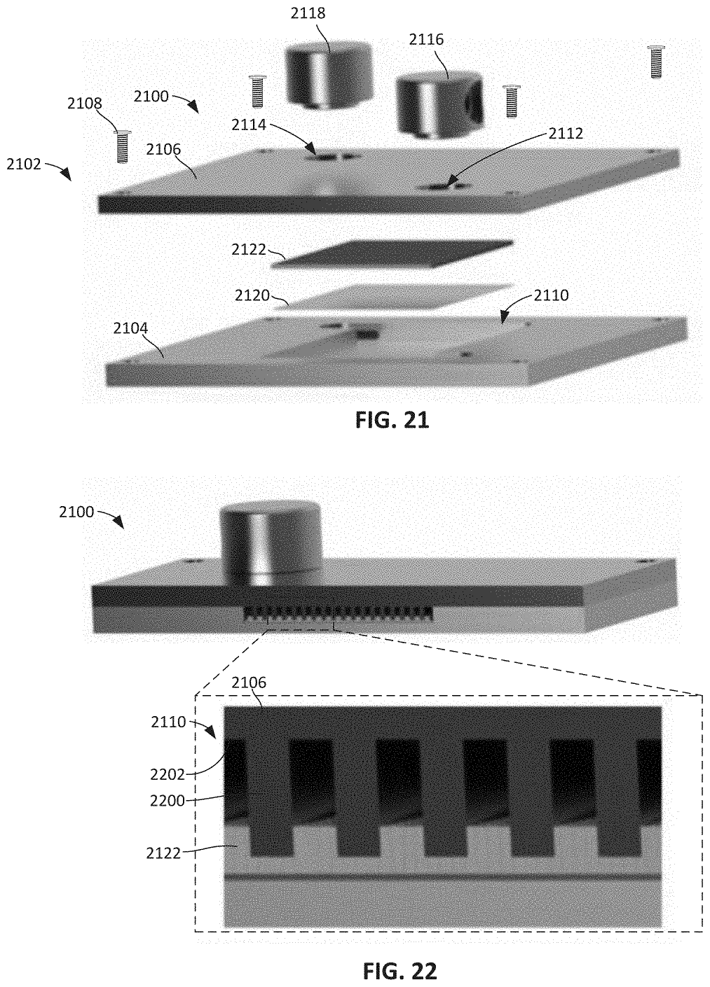

FIG. 21 is an exploded view of another example cold plate 2100 that may implement the cold plate 1704. The cold plate 2100 includes a body 2102, a base 2104, a lid 2106, fasteners 2108 for coupling the lid 2106 and the base 2104, a cavity 2110 defined in the base 2104, an inlet opening 2112 and an outlet opening 2114 in the lid 2106, connectors 2116, 2118, and braze film 2120. The cold plate 2100 is similar to the cold plate 1800 disclosed above, except as noted in further detail herein. Thus, to avoid redundancy, any of the example structures, features, and/or materials disclosed above in connection with the cold plate 1800 can likewise apply to the cold plate 2100.

In the illustrated example, the cold plate 2100 includes metal foam 2122, such as copper foam or aluminum foam. The example metal foam 2122 may have any of the example properties discussed above in connection with the fin bank 1828. However, in this example, the metal foam 2122 is substantially rectangular and does not include fins. When the cold plate 2100 is assembled, the metal foam 2122 can be coupled (e.g., via the braze film 2120) to an inner surface of the base 2104 in the cavity 2110.

FIG. 22 is a cross-sectional view of the example cold plate 2100 in an assembled state. FIG. 22 includes a callout showing an enlarged view of the inside of the cavity 2110. As shown in FIG. 22, the lid 2106 has a plurality of fins 2200 (one of which is referenced in FIG. 22) extending from a second side 2202 of the lid 2106. The fins 2200 are parallel to and spaced apart from each other. In this example, the fins 2200 are straight. In other examples, the fins 2200 can be curved or shaped differently. When the cold plate 2100 is assembled, as shown in FIG. 22, the fins 2200 extend into the cavity 2110 and engage the metal foam 2122. In some examples, as shown in FIG. 22, the fins 2200 extend into and compress certain sections of the metal foam 2122. In some examples, the sections of the metal foam 2122 compressed by the fins 2200 have a lower porosity than the sections of the metal foam 2122 between the fins 2200. The fins 2200 improve stiffness and durability of the cold plate 2100. During operation, the fins 2200 improve heat transfer to the cooling fluid, and the metal foam 2122 acts as a wicking structure that aids in moving the cooling fluid through the cavity 2110. Also, the metal foam 2122 exhibits an increase in bubble formation along the surfaces, which improves the cooling capacity of the cold plate 2100. In some examples, when the cold plate 2100 is assembled, the metal foam 2122 functions similarly to a fin bank because the uncompressed sections of the metal foam 2122 form a plurality of fins extending from a base, similar to the fin bank 1828 disclosed above. Therefore, the metal foam 2122 of this example may also be referred to as a fin bank.

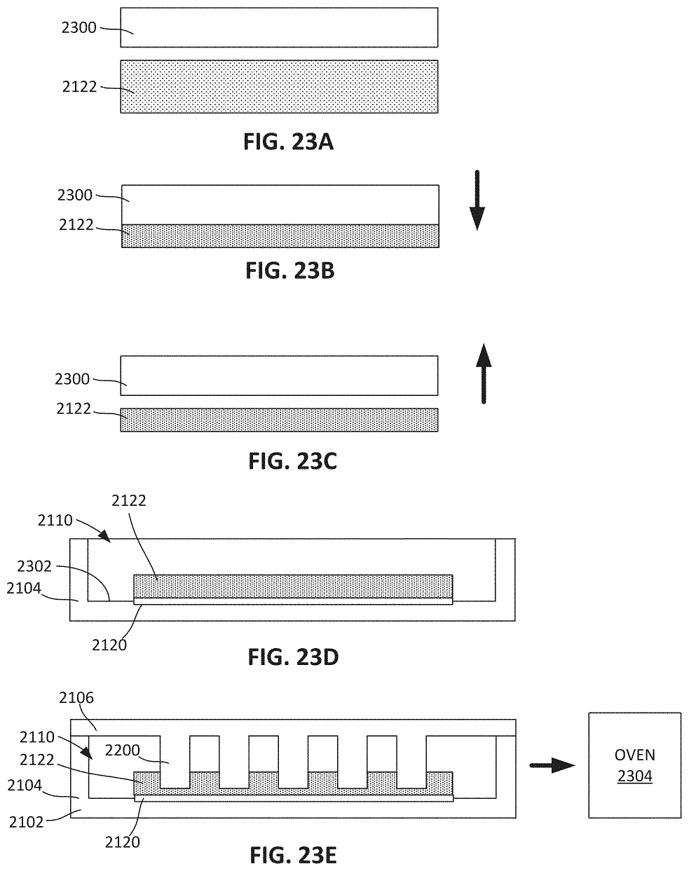

FIGS. 23A-23E show an example sequence of operations to form the example metal foam 2122 and assemble the example cold plate 2100. FIG. 23A shows the example metal foam 2122. In some examples, the metal foam 2122 starts as a block of metal foam that is compressed to a desired thickness and porosity. For example, FIG. 23A shows an example tool 2300 (e.g., a compression plate). As shown in FIG. 23B, the tool 2300 is pushed onto the metal foam 2122 and compresses the metal foam 2122. The metal foam 2122 can be compressed to a desired thickness and/or porosity. The tool 2300 may be pushed into the metal foam 2122 manually or via an automated machine. As shown in FIG. 23C, the tool 2300 is removed. After the tool 2300 is removed, the metal foam 2122 maintains the compressed thickness. However, the metal foam 2122 has a lower porosity after compression. This may be advantageous for wicking cooling fluid through the cavity 2110.

As shown in FIG. 23D, the metal foam 2122 is then disposed in the cavity 2110 of the base 2104. In some examples, the braze sheet 2120 and/or braze paste is disposed on a surface 2302 of the base 2104 in the cavity 2110, between the metal foam 2122 and the surface 2302. In some examples, such as in high pressure applications, braze film and/or braze past can be disposed on the top side of the metal foam 2122.

Then, as shown in FIG. 23E, the lid 2106 is coupled (e.g., via the fasteners 2108 (FIG. 21)) to the base 2104. When the lid 2106 is coupled to the base 2104, the fins 2200 (one of which is referenced in FIG. 23E) extend into the cavity 2110 and engage or contact the metal foam 2122. In some examples, as shown in FIG. 23E, the fins 2200 compress sections of the metal foam 2122. Then, the cold plate 2100 can be placed in a brazing oven 2304 and heated, which melts or softens the braze film 2120 and/or paste to couple the metal foam 2122 to the body 2102.

An example method of manufacturing disclosed herein includes compressing a block of metal foam with a tool. The example method can further include disposing the metal foam in a cavity of a body of a cold plate. For example, as shown in FIGS. 23A-23C, the metal foam 2122 is compressed with the tool 2300. Then, as shown in FIG. 23D, the block of the metal foam 2122 is disposed in the cavity 2110 of the base 2104 of the cold plate 2100. In some examples, the method includes coupling a lid to the base, and the lid may have a plurality of fins such that when the lid is coupled to the base, the fins extend into the cavity and engage the block of metal foam. For example, as shown in FIG. 23E, when the lid 2106 is coupled to the base 2104, the fins 2200 extend into the cavity 2110 and engaged the block of the metal foam 2122. In some examples, the method includes coupling the block of metal foam to the body of the cold plate. In some examples, the block of metal foam is coupled to the body via brazing. Therefore, in some examples, the method may include heating the cold plate in a brazing oven to couple the block of metal foam to the body. For example, as shown in FIG. 23E, the cold plate 2100 can be heated in the brazing oven 2304 to melt the braze film 2120 and couple the block of the metal foam 2122 to the body 1802. In other examples, the metal foam 2122 can be coupled to the body 2102 in other manners.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that improve the cooling capability of a cold plate in a liquid cooling system. Examples disclosed herein advantageously utilize metal foam material, which promotes (e.g., increases) formation of smaller bubbles that form on the foam and detach from the foam more quickly, compared to known structures in known cold plates. This fast formation/detachment reduces wall superheat (i.e., the difference between the wall temperature and the cooling liquid temperature) and improves the cooling capability of the cold plate. Further, metal foam is relatively inexpensive. Therefore, examples disclosed herein result in a less expensive, two-phase cooling cold plate. Also, metal foam is light weight, which reduces weight of the overall cold plate.

Examples and combinations of examples disclosed herein include the following:

Example 1 is a cold plate for an electronic device. The cold plate comprises a body defining a cavity. The body has an inlet opening and an outlet opening fluidically coupled to the cavity such that a fluid passageway is defined between the inlet opening and the outlet opening. The cold plate also comprises metal foam in the cavity.

Example 2 includes the cold plate of Example 1, wherein the metal foam is an open-cell-structure foam material.

Example 3 includes the cold plate of Examples 1 or 2, wherein the metal foam is copper foam or aluminum foam.

Example 4 includes the cold plate of any of Examples 1-3, wherein the metal foam has a relative density of 3-12%.

Example 5 includes the cold plate of any of Examples 1-4, wherein the metal foam is a compressible metal foam.

Example 6 includes the cold plate of any of Examples 1-5, wherein the metal foam is included in a fin bank. The fin bank includes a base plate and a plurality of fins extending from the base plate.

Example 7 includes the cold plate of Example 6, wherein the metal foam in the base plate has a lower porosity than the metal foam in the fins.

Example 8 includes the cold plate of Examples 6 or 7, wherein the fins are parallel to and spaced apart from each other.

Example 9 includes the cold plate of any of Examples 6-8, wherein the body includes a base and a lid, the cavity defined in the base.

Example 10 includes the cold plate of Example 9, wherein the fins are engaged with the lid.

Example 11 includes the cold plate of any of Examples 6-10, wherein the base plate of the fin bank is coupled to the base via brazing.

Example 12 includes the cold plate of Example 11, further including braze film between the base plate and a surface of the base in the cavity.

Example 13 includes the cold plate of any of Examples 1-12, wherein the metal foam increases bubble formation and detachment.

Example 14 includes the cold plate of any of Examples 1-13, wherein the metal foam reduces wall superheat of the cold plate.

Example 15 is a method comprising compressing a block of metal foam with a tool to form a fin bank, the fin bank including a base plate and a plurality of fins extending from the base, and disposing the fin bank in a cavity of a body of a cold plate.

Example 16 includes the method of Example 15, further including heating the cold plate in a brazing oven to couple the fin bank to the body.

Example 17 includes the method of Examples 15 or 16, wherein the metal foam in the base plate has a lower porosity than the metal foam in the fins.

Example 18 is a cold plate for an electronic device. The cold plate comprises a base defining a cavity, metal foam in the cavity, and a lid having a plurality of fins. The fins extend into the cavity and engage with the metal foam.

Example 19 includes the cold plate of Example 18, wherein the metal foam is coupled to the base via brazing.

Example 20 includes the cold plate of Examples 18 or 19, wherein the metal foam is an open-cell-structure foam material.

Example 21 is a method comprising disposing a block of metal foam in a cavity of a base of a cold plate and coupling a lid to the base, the lid having a plurality of fins, such that when the lid is coupled to the base the fins extend into the cavity and engage the block of metal foam.

Example 22 includes the method of Example 21, further including heating the cold plate in a brazing oven to couple the block of metal foam to the base.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. A cold plate for an electronic device, the cold plate comprising:
a body defining a cavity, the body having an inlet opening and an outlet opening fluidically coupled to the cavity such that a fluid passageway is defined between the inlet opening and the outlet opening; and
metal foam in the cavity.

2. The cold plate of claim 1, wherein the metal foam is an open-cell-structure foam material.

3. The cold plate of claim 1, wherein the metal foam is copper foam or aluminum foam.

4. The cold plate of claim 1, wherein the metal foam has a relative density of 3-12%.

5. The cold plate of claim 1, wherein the metal foam is a compressible metal foam.

6. The cold plate of claim 1, wherein the metal foam is included in a fin bank, the fin bank includes a base plate and a plurality of fins extending from the base plate.

7. The cold plate of claim 6, wherein the metal foam in the base plate has a lower porosity than the metal foam in the fins.

8. The cold plate of claim 6, wherein the fins are parallel to and spaced apart from each other.

9. The cold plate of claim 6, wherein the body includes a base and a lid, the cavity defined in the base.

10. The cold plate of claim 9, wherein the fins are engaged with the lid.

11. The cold plate of claim 9, wherein the base plate of the fin bank is coupled to the base via brazing.

12. The cold plate of claim 11, further including braze film between the base plate and a surface of the base in the cavity.

13. The cold plate of claim 1, wherein the metal foam increases bubble formation and detachment.

14. The cold plate of claim 1, wherein the metal foam reduces wall superheat of the cold plate.

15. A method comprising:
compressing a block of metal foam with a tool to form a fin bank, the fin bank including a base plate and a plurality of fins extending from the base; and
disposing the fin bank in a cavity of a body of a cold plate.

16. The method of claim 15, further including heating the cold plate in a brazing oven to couple the fin bank to the body.

17. The method of claim 15, wherein the metal foam in the base plate has a lower porosity than the metal foam in the fins.

18. A cold plate for an electronic device, the cold plate comprising:
a base defining a cavity;
metal foam in the cavity; and
a lid having a plurality of fins, the fins extend into the cavity and engage with the metal foam.

19. The cold plate of claim 18, wherein the metal foam is coupled to the base via brazing.

20. The cold plate of claim 18, wherein the metal foam is an open-cell-structure foam material.

21. A method comprising:
disposing a block of metal foam in a cavity of a base of a cold plate; and
coupling a lid to the base, the lid having a plurality of fins, such that when the lid is coupled to the base the fins extend into the cavity and engage the block of metal foam.

22. The method of claim 21, further including heating the cold plate in a brazing oven to couple the block of metal foam to the base.
